(19) United States
(12) Patent Application Publication
(10) Pub. No.: US 2022/0038066 A1
(43) Pub. Date: Feb. 3, 2022

(54) Heterogeneous Semiconductor Transceiver Integrated Circuit

(71) Applicant: David Scott Farkas, LADERA RANCH, CA (US)

(72) Inventor: David Scott Farkas, LADERA RANCH, CA (US)

(21) Appl. No.: 16/947,403

(22) Filed: Jul. 30, 2020

(51) Int. Cl. H03F 3/24; H01L 23/00

(52) U.S. Cl. CPC H03F 3/245; H01L 24/16; H01L 2224/16145; H01L 2924/10253; H01L 2924/10272; H03F 2200/294; H01L 2924/1033; H01L 2924/10335; H01L 2924/14215; H01L 2924/143; H01L 2924/10329

(57) ABSTRACT

A transceiver integrated circuit comprised of multiple semiconductor technologies that are heterogeneously integrated. The main functions of the transceiver integrated circuit being a power amplifier, low noise amplifier, switch and digital functions. Each function is designed in the desired semiconductor technology where the critical parts of that semiconductor technology are combined with passive components of that function on another semiconductor technology. The result is a transceiver integrated circuit with improved performance and lower cost.

### BACKGROUND OF THE INVENTION

### Field of the Invention

The present invention is in the field of transceiver integrated circuits composed of multiple semiconductor technologies.

### Description of the Related Art

Many electronic systems use wireless electromagnetic transmission. Such systems include data transmission technologies that operate over a wide range of frequencies, including, but not limited to, microwave and millimeter-wave systems. The systems include communications networks such as cellular networks, satellite systems, fixed wireless networks, and the like, for which the demand is increasing. In addition, the demand for advanced electronic systems for defense and military applications such as radar systems, reconnaissance and surveillance systems, weapons systems, and homeland security systems is increasing. With the increased demand for these products, a need exists for improved performance of transceiver integrated circuits (IC) used in these systems.

### SUMMARY OF THE INVENTION

In view of the need for improved performance of transceiver integrated circuits, a need exists to create these integrated circuits using multiple semiconductor technologies that when heterogeneously integrated have improved performance over homogeneous semiconductor integrated circuits.

In accordance with the exemplary embodiments disclosed herein is an improved transceiver integrated circuit design that combines multiple semiconductor technologies.

### BRIEF DESCRIPTION OF THE DRAWINGS

Embodiments in accordance with aspects of the present invention are described below in connection with the attached drawings in which:

FIG. 1 illustrates an example of a transceiver integrated circuit having active transistor devices and/or passive components attached to a host semiconductor wafer which contains passive components and/or active transistor devices;

FIG. 2 illustrates active transistor devices and/or passive components;

FIG. 3 illustrates active transistor devices and/or passive components;

FIG. 4 illustrates active transistor devices and/or passive components;

FIG. 5 illustrates active transistor devices and/or passive components;

### DETAILED DESCRIPTION OF PREFERRED EMBODIMENTS

The transceiver integrated circuit disclosed herein with respect to exemplary embodiments. The embodiments are disclosed to illustrate a heterogeneous transceiver integrated circuit for improved performance.

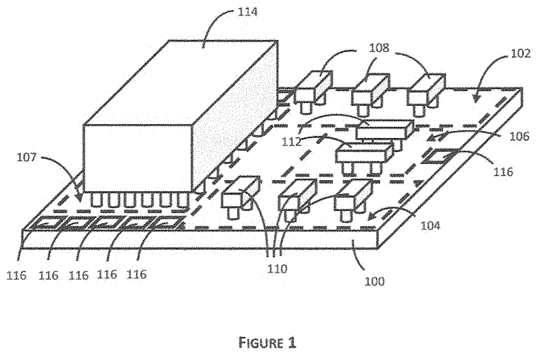

FIG. 1 illustrates a transceiver integrated circuit comprised of a host semiconductor wafer 100 which contains passive components and/or active transistor devices. The host semiconductor wafer 100 is composed of unique integrated circuit function including a power amplifier 102, a low noise amplifier 104, a switch 106, and digital control 107. One skilled in the art will recognize that these functions are main components of a transceiver integrated circuit, but other functions can be added including but not limited to phase shifters, attenuators, mixers, multipliers, etc. One skilled in the art will also recognize that some transceiver integrated circuits may not require all the components mentioned in which case the circuit may include less functions. One skilled in the art will also recognize that this transceiver integrated circuit consists of a single channel and that a transceiver integrated circuit can contain any number of channels.

Each integrated circuit function in a transceiver needs a different semiconductor technology which is ideally suited for that function. For example, gallium nitride is ideally suited for the power amplifier and switch while indium phosphide is ideally suited for a low noise amplifier. Silicon technology is ideally suited for digital control. One skilled in the art will recognize that these semiconductor technologies are just one example of technologies that can be used for each function and that there are other semiconductor technologies that can be used for each function based on the transceiver integrated circuit requirements.

Historically, transceivers are comprised of multiple individual semiconductor integrated circuits in multiple technologies. Using multiple integrated circuits in this manner leads to high cost due to the large area of semiconductor material used as well as the packaging of each integrated circuit. Packaging of each integrated circuit also reduced the performance as it adds loss to the electromagnetic signals that must travel from the integrated circuit to the exterior of the package.

Using the heterogeneous integration approach shown in FIG. 1, a low-cost semiconductor technology can be used for the host semiconductor wafer 100 which can include portions of each circuit function. Smaller pieces of other technologies containing just their critical components 108, 110, 112, 114 can be added to the host wafer through a direct bonded connection. Using smaller pieces of these semiconductor technologies substantially reduces cost and improves performance of the transceiver integrated circuit.

The power amplifier 102 is comprised of passive components and/or active devices located on the host wafer 100 and active transistor devices and/or passive components from another semiconductor technology 108 that are directly bonded to the host wafer 100. One skilled in the art will recognize that passive devices refers to circuit elements such as, but not limited to, inductors, capacitors, resistors that can be in lumped element or distributed form. One skilled in the art will also recognize that active transistor devices can include any active transistor technology such as, but not limited to, field-effect transistors (FET), high electron mobility transistors (HEMT), heterojunction bipolar transistors (BJT), diodes, etc.

The low noise amplifier 104 is comprised of passive components and/or active devices located on the host wafer 100 and active transistor devices and/or passive components from another semiconductor technology 110 that are directly bonded to the host wafer 100.

The switch 106 is comprised of passive components and/or active devices located on the host wafer 100 and active transistor devices and/or passive components from another semiconductor technology 112 that are directly bonded to the host wafer 100.

The digital control 107 is comprised of passive components and/or active devices located on the host wafer 100 and active transistor devices and/or passive components from another semiconductor technology 114 that are directly bonded to the host wafer 100. The host semiconductor wafer also contains the input and output connections 116. One skilled in the art will recognize that any number of input and output connections can be included for, but not limited to, input signals, output signals, power, control, monitoring, etc. One skilled in the art will also recognize that the input and output connections can be on either top or bottom surface of the host wafer.

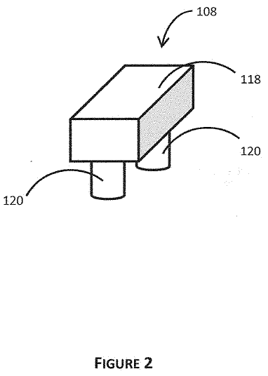

FIG. 2 shows the active transistor devices and/or passive components 108 that is comprised of a semiconductor material containing the active transistor devices and/or passive components 118 and metal bonding posts 120.

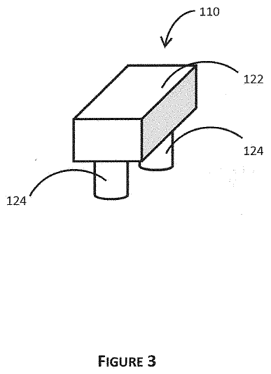

FIG. 3 shows the active transistor devices and/or passive components 110 that is comprised of a semiconductor material containing the active transistor devices and/or passive components 122 and metal bonding posts 124.

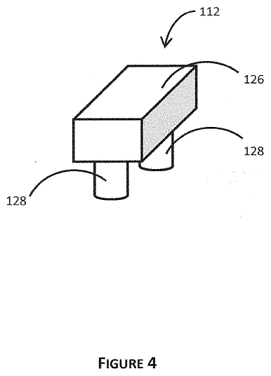

FIG. 4 shows the active transistor devices and/or passive components 112 that is comprised of a semiconductor material containing the active transistor devices and/or passive components 126 and metal bonding posts 128.

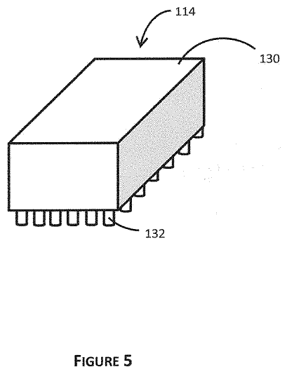

FIG. 5 shows the digital control 114 that is comprised of a semiconductor material containing the active transistor devices and/or passive components 130 and metal bonding posts 132.

What is claimed is:

1. The transceiver integrated circuit containing multiple semiconductor technologies heterogeneously integrated through the direct bonding of each component onto a host semiconductor wafer comprising a power amplifier, a low noise amplifier, a switch, and digital control functions.

2. The transceiver integrated circuit as defined in claim 1 further comprising:
A host semiconductor wafer comprised of silicon carbide;
A power amplifier comprised of gallium nitride active transistor devices bonded to the host semiconductor wafer containing the power amplifier passive components;
A low noise amplifier comprised of indium phosphide active transistor devices bonded to the host semiconductor wafer containing the low noise amplifier passive components;
A switch comprised of gallium nitride active transistor devices bonded to the host semiconductor wafer containing the switch passive components;
A digital control component comprised of silicon active transistor devices and passive components bonded to the host wafer.

3. The transceiver integrated circuit as defined in claim 1 further comprising:
A host semiconductor wafer comprised of silicon carbide;
A power amplifier comprised of gallium arsenide active transistor devices bonded to the host semiconductor wafer containing the power amplifier passive components;
A low noise amplifier comprised of indium phosphide active transistor devices bonded to the host semiconductor wafer containing the low noise amplifier passive components;
A switch comprised of gallium arsenide active transistor devices bonded to the host semiconductor wafer containing the switch passive components;
A digital control component comprised of silicon active transistor devices and passive components bonded to the host wafer.

4. The transceiver integrated circuit as defined in claim 1 further comprising:
A host semiconductor wafer comprised of silicon carbide;
A power amplifier comprised of gallium nitride active transistor devices bonded to the host semiconductor wafer containing the power amplifier passive components;
A low noise amplifier comprised of indium phosphide active transistor devices bonded to the host semiconductor wafer containing the low noise amplifier passive components;
A switch comprised of gallium arsenide active transistor devices bonded to the host semiconductor wafer containing the switch passive components;
A digital control component comprised of silicon active transistor devices and passive components bonded to the host wafer.
